(19) United States
(12) Patent Application Publication
(10) Pub. No.: US 2013/0049080 A1
(43) Pub. Date: Feb. 28, 2013

(54) SEMICONDUCTOR DEVICE AND MANUFACTURING METHOD OF SEMICONDUCTOR DEVICE

(71) Applicant: Kimitoshi OKANO, Kanagawa (JP)

(72) Inventor: Kimitoshi OKANO, Kanagawa (JP)

(73) Assignee: Kabushiki Kaisha Toshiba, Tokyo (JP)

(21) Appl. No.: 13/563,058

(22) Filed: Jul. 31, 2012

(30) Foreign Application Priority Data
Aug. 24, 2011 (JP) 2011-182828

(51) Int. Cl. H01L 21/336; H01L 29/78

(52) U.S. Cl. 257/288; 438/283; 257/E29.255; 257/E21.421

(57) ABSTRACT

According to one embodiment, a semiconductor device includes a fin-type semiconductor, a gate electrode that is formed on a side surface of the fin-type semiconductor with a gate dielectric film therebetween in a state where both end portions of the fin-type semiconductor are exposed, source/drain formed in both end portions of the fin-type semiconductor, an offset spacer and a sidewall spacer that are formed on a side surface of the source/drain and a side surface of the gate electrode in a state where a surface of an upper portion of the fin-type semiconductor is exposed, and a silicide layer that is formed on a surface of the source/drain in the upper portion of the fin-type semiconductor.

### CROSS-REFERENCE TO RELATED APPLICATIONS

This application is based upon and claims the benefit of priority from Japanese Patent Application No. 2011-182828, filed on Aug. 24, 2011; the entire contents of which are incorporated herein by reference.

### FIELD

Embodiments described herein relate generally to a semiconductor device and a manufacturing method of a semiconductor device.

### BACKGROUND

In field-effect transistors, short channel effects become significant in accordance with the scaling thereof, and a high concentration of a channel impurity is required to suppress the short channel effects in conventional single gate transistors. However, it is known that increasing the concentration of a channel impurity causes problems, such as a reduction in the on-current due to a decrease in carrier mobility in the channel, an increase in threshold voltage variation due to impurity fluctuations, and an increase in junction leakage current, therefore the short channel effects need to be suppressed without increasing the concentration of a channel impurity to improve the performance of scaled transistors.

A multi-gate transistor, in which a plurality of gate electrodes is arranged on a channel, has been proposed as a method of suppressing the short channel effects without increasing the concentration of a channel impurity. Because a multi-gate transistor controls channel potential with a plurality of gate electrodes, the effect of the gate electrodes on the channel potential can be made higher than that of a drain electrode and therefore the short channel effects can be suppressed without increasing the concentration of a channel impurity. In a fin transistor, which is a type of multi-gate transistors, the channel width is increased by increasing the height of the fin and therefore the on-current can be increased without increasing a footprint, thus the fin transistor is effective for use, for example, as a cell transistor in a memory that requires a high drive current.

In a similar manner to a planar transistor, in a fin transistor, generally, silicide is formed on source/drain and contacts are formed on the silicide, however, because contact resistance between the source/drain and the silicide is a main component of a parasitic resistance, reducing the contact resistance is important for improving performance. There are various effective methods for reducing this contact resistance, such as reducing the Schottky barrier height of a silicide material, increasing the impurity concentration in the interface between the source/drain and the silicide, and increasing the contact area between the source/drain and the silicide.

In order to increase the contact area between the source/drain and the silicide in the fin transistor, it is known as an effective technology to silicide the surface of the fin of the source/drain after thickening the fin by epitaxial growth.

There are two types of fin transistors: a fin transistor formed on a bulk semiconductor substrate, and a fin transistor formed on a SOI (Silicon On Insulator) substrate. The former is preferable in terms of the cost of a semiconductor wafer, combining with a planar transistor, suppression of self-heating, and the like.

The former fin transistor needs a punch-through stopper at the fin channel bottom to prevent leakage current between the source and the drain, which results in the formation of a PN junction at the bottom of the source/drain. Therefore, if the silicide on the source/drain and this PN junction become close to each other, junction leakage current increases. As described above, in a fin transistor, the contact resistance between the source/drain and the silicide can be reduced by increasing the contact area between the source/drain and the silicide by forming the silicide on the fin side surface, however, it is necessary to prevent the silicide from getting close to the PN junction at the source/drain bottom and junction leakage current from increasing.

### BRIEF DESCRIPTION OF THE DRAWINGS

FIG. 1A is a plan view illustrating a schematic configuration of a semiconductor device according to a first embodiment, FIG. 1B is a cross-sectional view illustrating a schematic configuration of the semiconductor device cut along line A-A in FIG. 1A, and FIG. 1C is a cross-sectional view illustrating a schematic configuration of the semiconductor device cut along line B-B in FIG. 1A;

FIG. 2A to FIG. 2C are cross-sectional views illustrating a manufacturing method of a semiconductor device according to a second embodiment;

FIG. 3A to FIG. 3C are cross-sectional views illustrating the manufacturing method of the semiconductor device according to the second embodiment;

FIG. 4A to FIG. 4C are cross-sectional views illustrating the manufacturing method of the semiconductor device according to the second embodiment;

FIG. 5A to FIG. 5C are cross-sectional views illustrating the manufacturing method of the semiconductor device according to the second embodiment;

FIG. 6A to FIG. 6C are cross-sectional views illustrating the manufacturing method of the semiconductor device according to the second embodiment;

FIG. 7A to FIG. 7C are cross-sectional views illustrating the manufacturing method of the semiconductor device according to the second embodiment;

FIG. 8A to FIG. 8C are cross-sectional views illustrating the manufacturing method of the semiconductor device according to the second embodiment;

FIG. 9A to FIG. 9C are cross-sectional views illustrating the manufacturing method of the semiconductor device according to the second embodiment;

FIG. 10A to FIG. 100 are cross-sectional views illustrating the manufacturing method of the semiconductor device according to the second embodiment;

FIG. 11A to FIG. 11C are cross-sectional views illustrating the manufacturing method of the semiconductor device according to the second embodiment;

FIG. 12A to FIG. 12C are cross-sectional views illustrating the manufacturing method of the semiconductor device according to the second embodiment;

FIG. 13A to FIG. 13C are cross-sectional views illustrating the manufacturing method of the semiconductor device according to the second embodiment;

FIG. 14A to FIG. 14C are cross-sectional views illustrating the manufacturing method of the semiconductor device according to the second embodiment;

FIG. 15A to FIG. 15C are cross-sectional views illustrating the manufacturing method of the semiconductor device according to the second embodiment;

FIG. 16A to FIG. 16C are cross-sectional views illustrating the manufacturing method of the semiconductor device according to the second embodiment;

FIG. 17A to FIG. 17C are cross-sectional views illustrating the manufacturing method of the semiconductor device according to the second embodiment;

FIG. 18A to FIG. 18C are cross-sectional views illustrating the manufacturing method of the semiconductor device according to the second embodiment;

FIG. 19A to FIG. 19C are cross-sectional views illustrating the manufacturing method of the semiconductor device according to the second embodiment; and

FIG. 20 is a diagram illustrating a relationship between a fin projection amount Ef above a sidewall spacer 8 in FIG. 10 and on-current Ion.

### DETAILED DESCRIPTION

In general, according a semiconductor device in embodiments, a fin-type semiconductor, a gate dielectric film, a gate electrode, a top layer, source/drain, an offset spacer, a sidewall spacer, and a silicide layer are included. The gate electrode is formed on a side surface of the fin-type semiconductor with the gate dielectric film therebetween. The top layer is formed on the upper portion of the gate electrode. The source/drain are formed in both end portions (regions that do not overlap the gate electrode) of the fin-type semiconductor. The offset spacer and the sidewall spacer are formed on side surfaces of the gate electrode and the source/drain in a state where a surface of an upper portion of the fin-type semiconductor is exposed. The silicide layer is formed on a surface of the source/drain.

A semiconductor device and a manufacturing method of the semiconductor device according to the embodiments will be explained below with reference to the drawings. The present invention is not limited to the following embodiments.

### First Embodiment

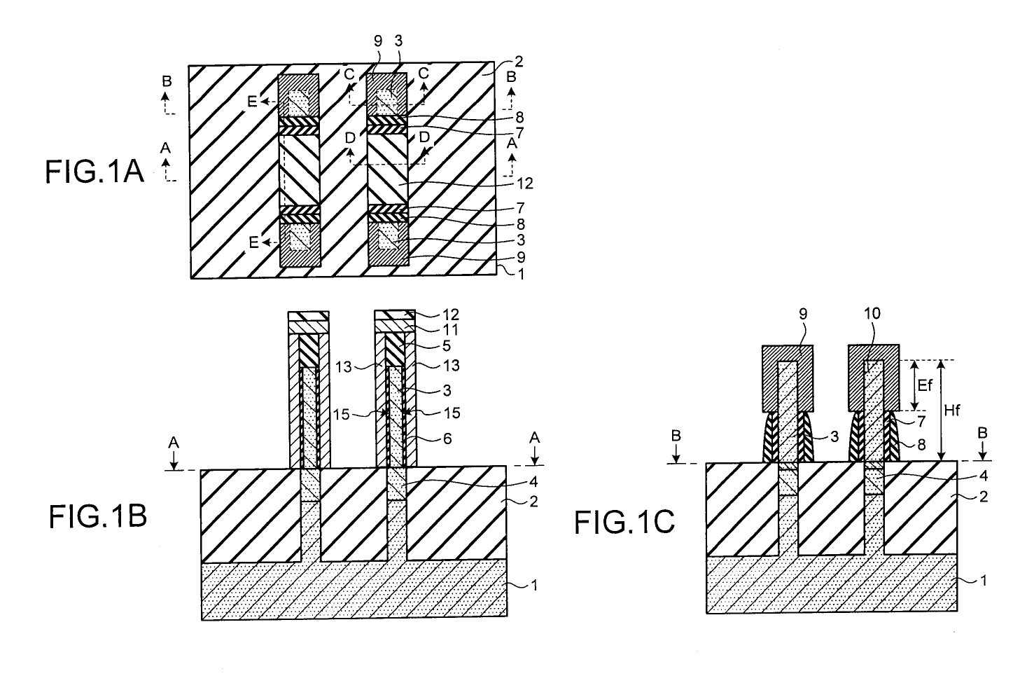

FIG. 1A is a plan view illustrating a schematic configuration of a semiconductor device according to the first embodiment, FIG. 1B is a cross-sectional view illustrating a schematic configuration of the semiconductor device cut along line A-A in FIG. 1A, and FIG. 1C is a cross-sectional view illustrating a schematic configuration of the semiconductor device cut along line B-B in FIG. 1A.

In FIG. 1A to FIG. 1B, a fin-type semiconductor 3 is formed on a semiconductor substrate 1. The materials of the semiconductor substrate 1 and the fin-type semiconductor 3 can be selected, for example, from Si, Ge, SiGe, GaAs, AlGaAs, InP, GaP, InGaAs, GaN, SiC, and the like. Moreover, the materials of the semiconductor substrate 1 and the fin-type semiconductor 3 may be the same or different from each other.

A buried dielectric layer 2 is formed on the semiconductor substrate 1 to bury the lower portion of the fin-type semiconductor 3. For example, a STI (Shallow Trench Isolation) structure can be used as the structure of the buried dielectric layer 2. For example, SiO₂ can be used as the material of the buried dielectric layer 2.

Gate electrodes 13 are formed on the side surfaces of the fin-type semiconductor 3 projecting above the buried dielectric layer 2 with a gate dielectric film 6 therebetween and a channel region 15 is formed in the fin-type semiconductor 3 opposite to the gate electrodes 13 with the gate dielectric film 6 therebetween. Source/drain formed of a high-concentration impurity diffusion layer 10 are provided in both end portions of the fin-type semiconductor 3. The high-concentration impurity diffusion layer 10 of the fin-type semiconductor 3 can be an N⁺-type impurity diffusion layer. In the channel region 15 of the fin-type semiconductor 3, the impurity concentration in the channel region 15 is preferably reduced to suppress variations in electrical characteristics of a field-effect transistor due to random dopant fluctuation and decrease in mobility in the channel region 15. The channel region 15 may be non-doped. In order to suppress the short channel effects even when the impurity concentration in the channel region 15 is sufficiently reduced, the fin width is preferably smaller than the gate length, more specifically, equal to or smaller than ⅔ of the gate length. The fin transistor can be a fully-depleted device by sufficiently reducing the impurity concentration in the channel.

For example, polycrystalline silicon can be used as the material of the gate electrode 13. Alternatively, the material of the gate electrode 13 may be selected, for example, from W, Al, TaN, Ru, TiAlN, HfN, NiSi, Mo, TiN, and the like. The material of the gate dielectric film 6 can be selected, for example, from SiO₂, HfO, HfSiO, HfSiON, HfAlO, HfAlSiON, La₂O₃, and the like.

Moreover, a punch-through stopper layer 4 is formed in the lower portion of the fin-type semiconductor 3 to prevent leakage current from flowing between the source and the drain due to the absence of the gate electrode on the fin side surface. The punch-through stopper layer 4 can be a P⁻-type impurity diffusion layer with respect to the source/drain that are N⁺-type impurity diffusion layers.

A cap layer 5 is formed on the fin-type semiconductor 3 and a hard mask layer 12 is formed on the upper portion of a top layer 11 on the cap layer 5 and the gate electrodes 13. For example, Si₃N₄ can be used as the materials of the cap layer 5 and the hard mask layer 12. The top layer 11 can cause the fin transistor to perform a double-gate operation by connecting the gate electrodes 13 divided by the cap layer 5. The top layer 11 can be used also as a wire connected to the gate electrodes 13. For example, high-melting-point metal, such as W, can be used as the material of the top layer 11.

Offset spacers 7 and sidewall spacers 8 are formed on both end portions of the fin-type semiconductor 3 in a state where the surface of the upper portion of the fin-type semiconductor 3 is exposed. For example, Si₃N₄ can be used as the materials of the offset spacer 7 and the sidewall spacer 8. A silicide layer 9 is formed on the surface of the exposed high-concentration impurity diffusion layer 10 of the fin-type semiconductor 3. For example, WSi, MoSi, NiSi, NiPtSi, or the like can be used as the silicide layer 9. The silicide layer 9 can be formed in a semiconductor layer formed on the upper portion of the fin-type semiconductor 3 in the source/drain. At this time, the source/drain in the upper portion of the fin-type semiconductor 3 can be formed not to be eroded by the silicide layer 9.

The silicide layer 9 can be spaced apart from a junction region 16 between the high-concentration impurity diffusion layer 10 and the punch-through stopper layer 4 by forming the offset spacers 7 and the sidewall spacers 8 in a state where the surface of the upper portion of the fin-type semiconductor 3 is exposed. Therefore, it is possible to suppress that metal included in the silicide layer 9 diffuses into the junction region and the junction leakage current increases. The distance between the silicide layer 9 and the junction region 16 is preferably 30 nm or larger to suppress an increase of the junction leakage current.

(Second Embodiment)

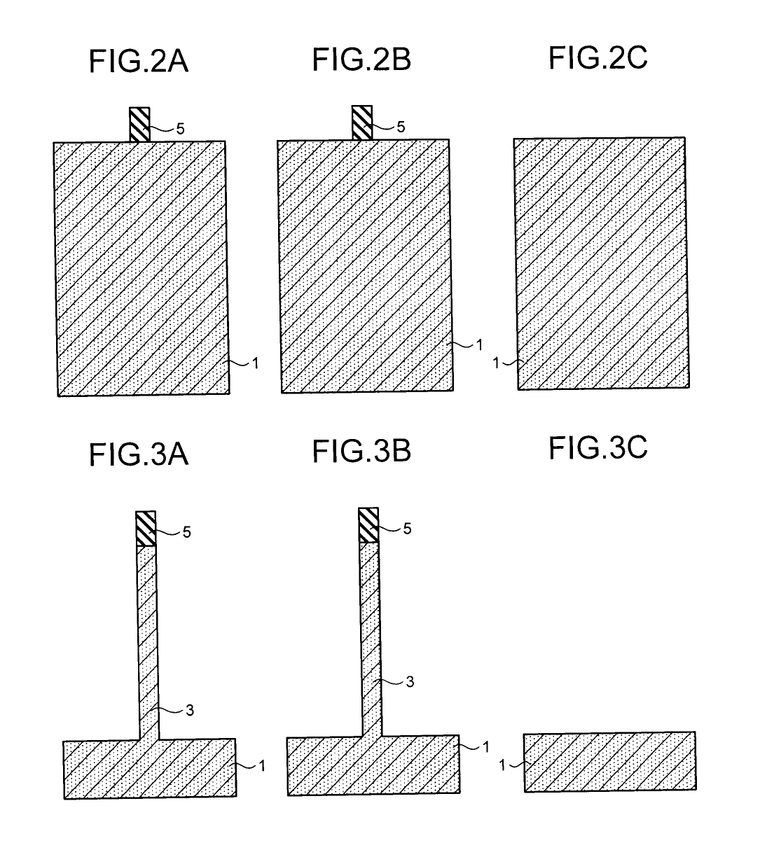

FIG. 2A to FIG. 19A, FIG. 2B to FIG. 19B, and FIG. 2C to FIG. 19C are cross-sectional views illustrating a manufacturing method of a semiconductor device according to the second embodiment. FIG. 2A to FIG. 19A are cross-sectional views cut along line C-C in FIG. 1A, FIG. 2B to FIG. 19B are cross-sectional views cut along line D-D in FIG. 1A, and FIG. 2C to FIG. 19C are cross-sectional views cut along line E-E in FIG. 1A.

In FIG. 2A to FIG. 2C, a hard mask material is deposited on the entire surface of the semiconductor substrate 1 by a method, such as the CVD. Then, the cap layer 5 is formed on the semiconductor substrate 1 by patterning the hard mask material by the photolithography technology and the etching technology.

Next, as shown in FIG. 3A to FIG. 3C, the fin-type semiconductor 3 is formed on the semiconductor substrate 1 by etching the semiconductor substrate 1 with the cap layer 5 as a mask.

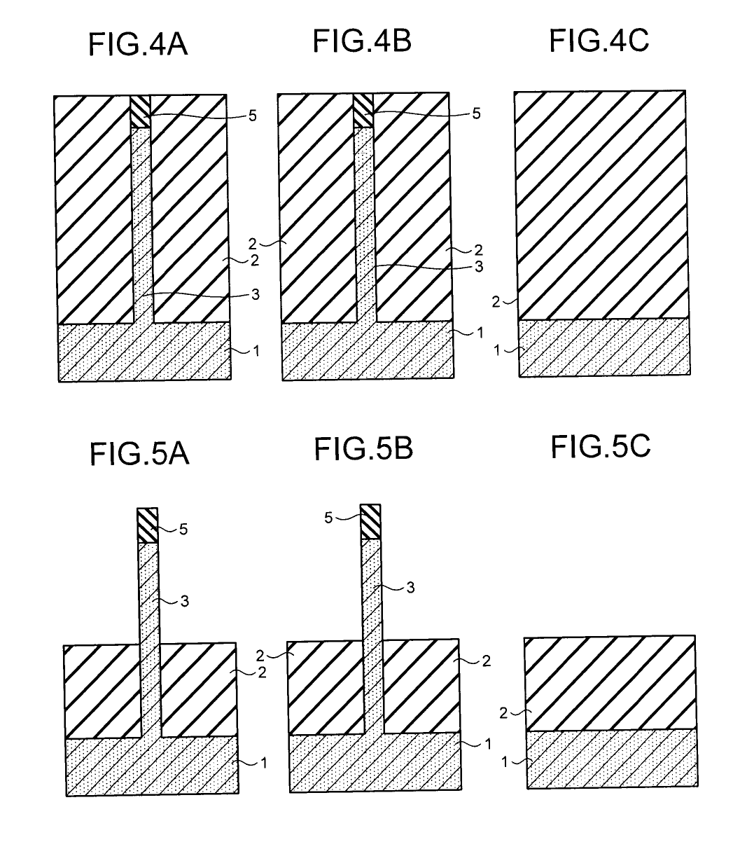

Next, as shown in FIG. 4A to FIG. 4C, the buried dielectric layer 2 is formed on the semiconductor substrate 1 to bury the fin-type semiconductor 3 by a method, such as the CVD. Then, the buried dielectric layer 2 is planarized by a method, such as the CMP. At this time, the cap layer 5 can be used as an etching stopper film in the CMP of the buried dielectric layer 2.

Next, as shown in FIG. 5A to FIG. 5C, the buried dielectric layer 2 is etched back to expose the upper portion of the fin-type semiconductor 3 from the buried dielectric layer 2 in a state where the lower portion of the fin-type semiconductor 3 is buried in the buried dielectric layer 2.

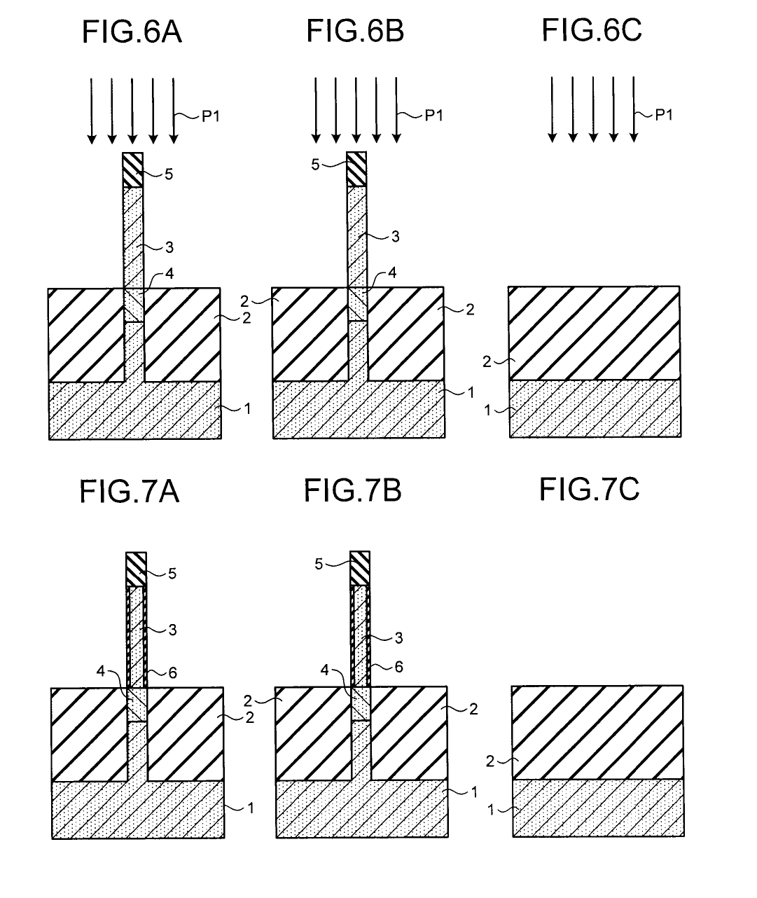

Next, as shown in FIG. 6A to FIG. 6C, a P-type impurity, such as B and In, is injected by ion implantation P1 vertically to the buried dielectric layer 2. At this time, large-angle scattering occurs with a certain probability in the surface layer of the buried dielectric layer 2 to cause the injected P-type impurity ions to be doped into the lower portion of the fin-type semiconductor 3, therefore the punch-through stopper layer 4 can be formed in the lower portion of the fin-type semiconductor 3.

Next, as shown in FIG. 7A to FIG. 7C, the gate dielectric film 6 is formed on the side surfaces of the fin-type semiconductor 3 projected from the buried dielectric layer 2 by a method, such as the thermal oxidation and the CVD.

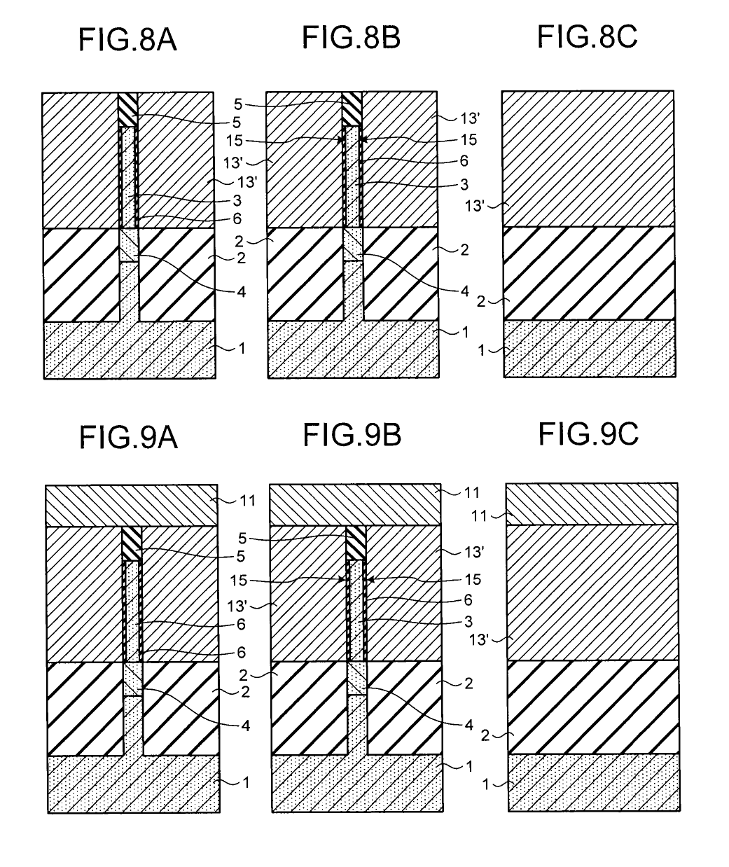

Next, as shown in FIG. 8A to FIG. 8C, a gate electrode material 13′ is formed on the buried dielectric layer 2 to bury the fin-type semiconductor 3 by a method, such as the CVD. Then, the gate electrode material 13′ is planarized by a method, such as the CMP. At this time, the cap layer 5 can be used as an etching stopper film in the CMP of the gate electrode material 13′.

Next, as shown in FIG. 9A to FIG. 9C, the top layer 11 is formed on the cap layer 5 and the gate electrode material 13′ by a method, such as sputtering.

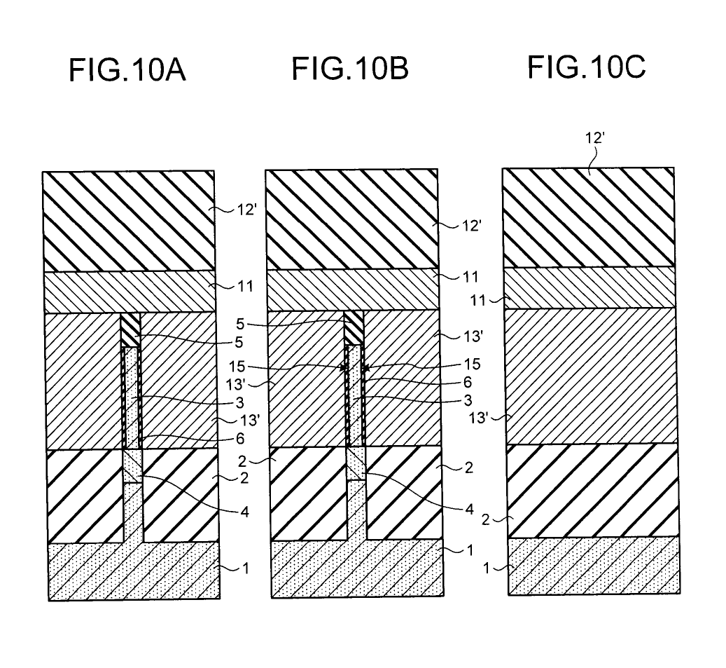

Next, as shown in FIG. 10A to FIG. 10C, a hard mask material 12′ is formed on the top layer 11 by a method, such as the CVD.

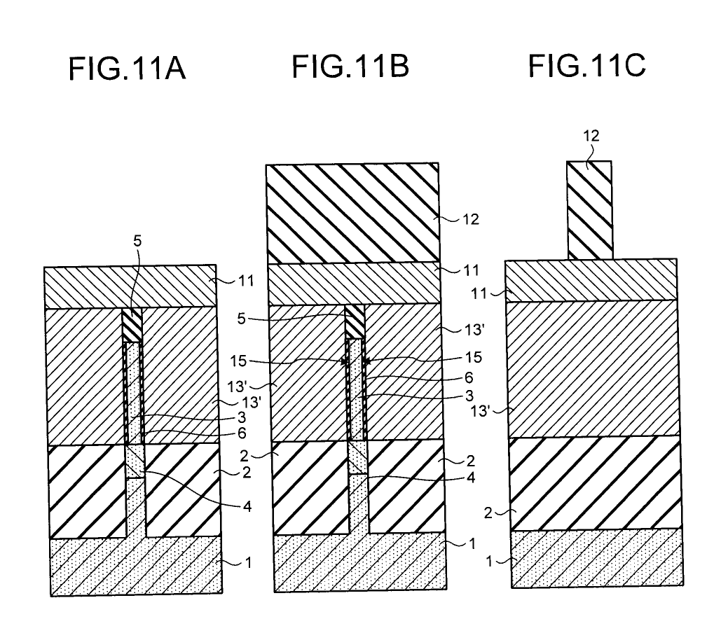

Next, as shown in FIG. 11A to FIG. 11C, the hard mask layer 12 is formed on the top layer 11 by patterning the hard mask material 12′ by the photolithography technology and the etching technology.

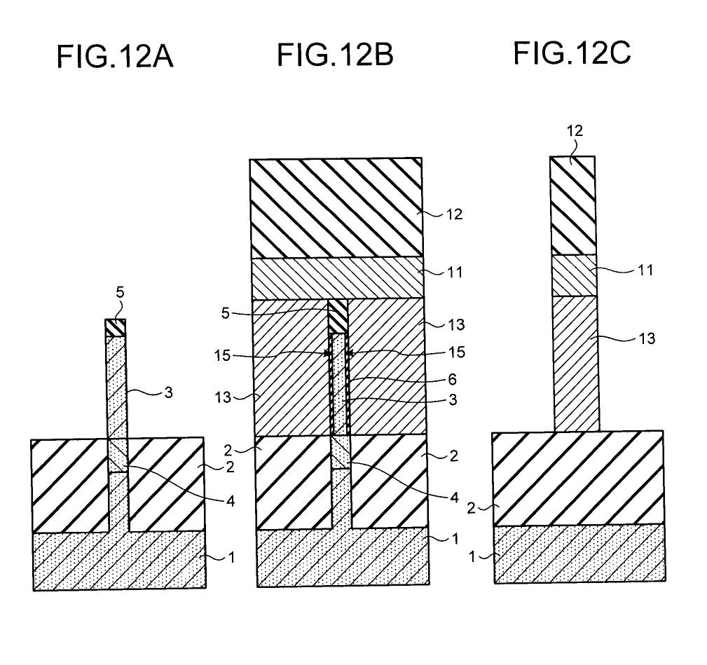

Next, as shown in FIG. 12A to FIG. 12C, the gate electrodes 13 are formed on the side surfaces of the fin-type semiconductor 3 projected above the buried dielectric layer 2 and the cap layer 5 by etching the top layer 11 and the gate electrode material 13′ with the hard mask layer 12 as a mask.

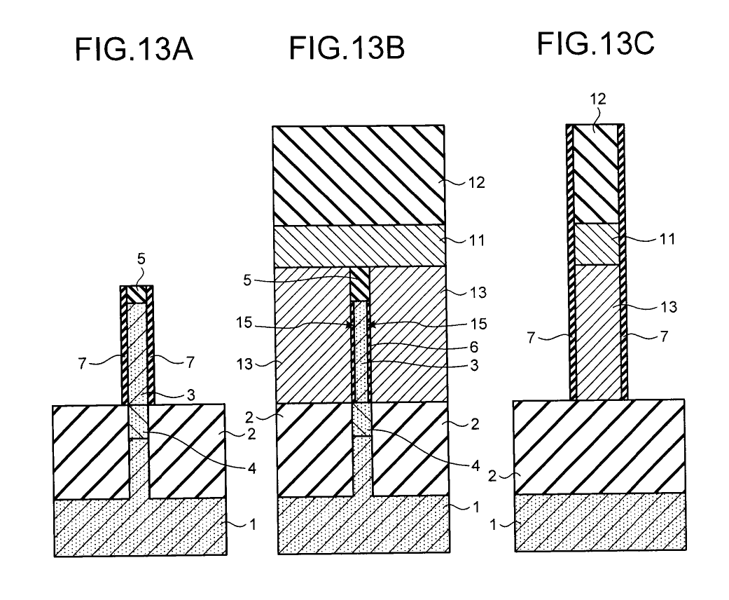

Next, as shown in FIG. 13A to FIG. 13C, the offset spacers 7 are formed on the side surfaces of both ends of the fin-type semiconductor 3 projected above the buried dielectric layer 2 and the side surfaces of the gate electrodes 13 by a method, such as the CVD and anisotropic etching. The offset spacers 7 on the buried dielectric layer 2, the cap layer 5, and the hard mask layer 12 can be removed by anisotropic etching.

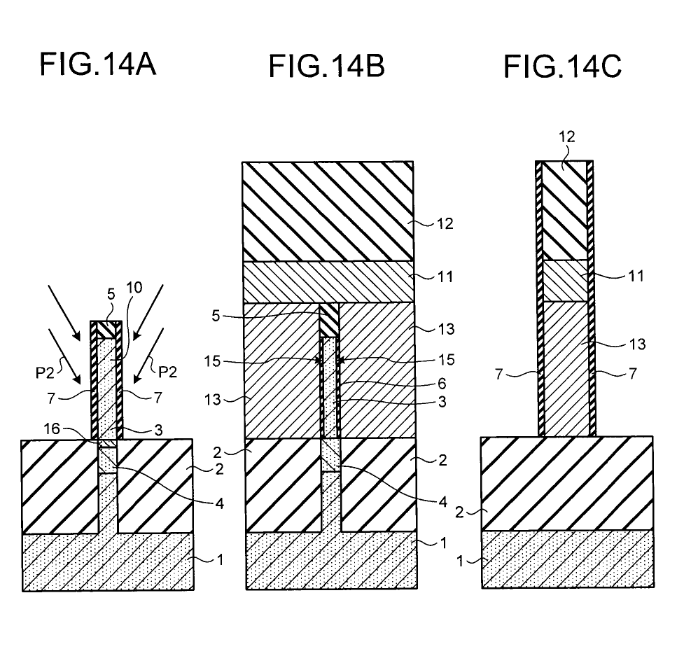

Next, as shown in FIG. 14A to FIG. 14C, an N-type impurity, such as As and P, is obliquely injected into both ends of the fin-type semiconductor 3 by ion implantation P2 to form the high-concentration impurity diffusion layer 10 in both ends of the fin-type semiconductor 3.

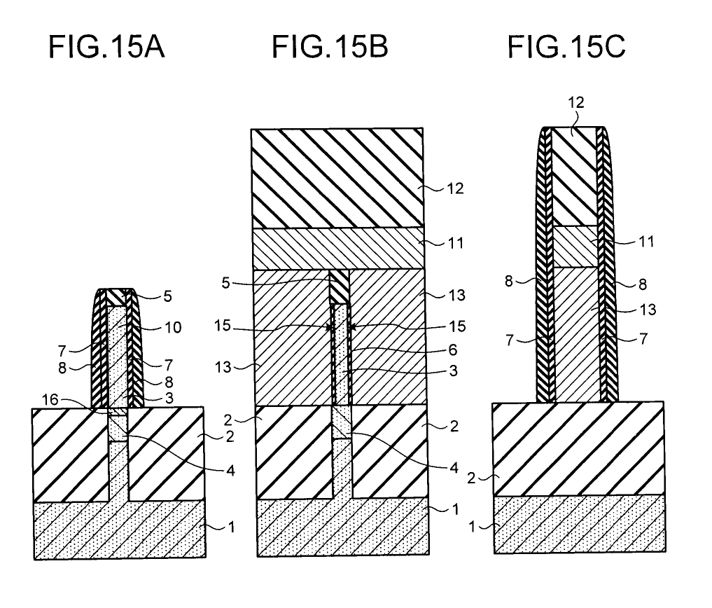

Next, as shown in FIG. 15A to FIG. 15C, the sidewall spacers 8 are formed on the outside of the offset spacers 7 formed on the side surfaces of both ends of the fin-type semiconductor 3 projected above the buried dielectric layer 2 and the side surfaces of the gate electrodes 13 by a method, such as the CVD and anisotropic etching. The sidewall spacers 8 on the buried dielectric layer 2, the cap layer 5, and the hard mask layer 12 can be removed by anisotropic etching.

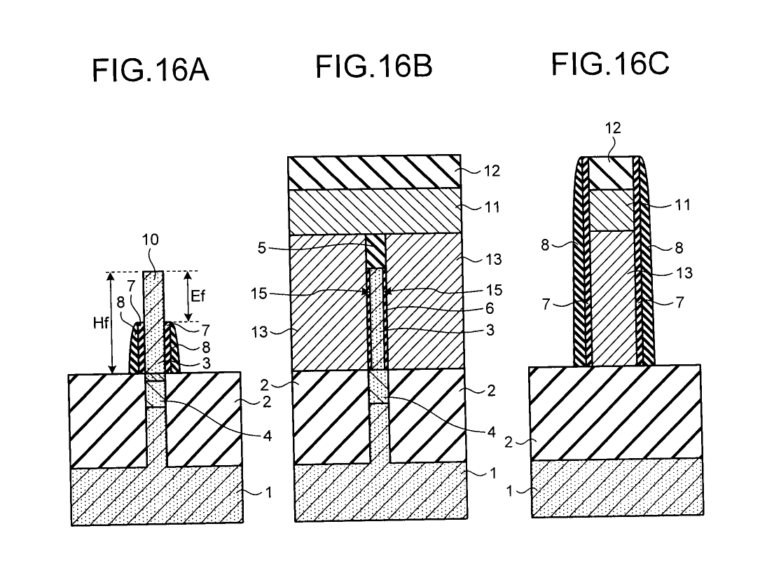

Next, as shown in FIG. 16A to FIG. 16C, the offset spacers 7 and the sidewall spacers 8 are etched back to expose the surface of the upper portion of both ends of the fin-type semiconductor 3. At this time, the cap layer 5 and the hard mask layer 12 are also etched, so that the cap layer 5 can be removed. Moreover, the side surfaces of the gate electrodes 13 and the top layer 11 can be kept completely covered with the offset spacers 7 and the sidewall spacers 8 by leaving part of the hard mask layer 12 on the top layer 11.

The gate electrodes 13 and the top layer 11 can be prevented from short-circuiting to the contacts formed on the source/drain by keeping the side surfaces of the gate electrodes 13 and the top layer 11 to be covered with the offset spacers 7 and the sidewall spacers 8.

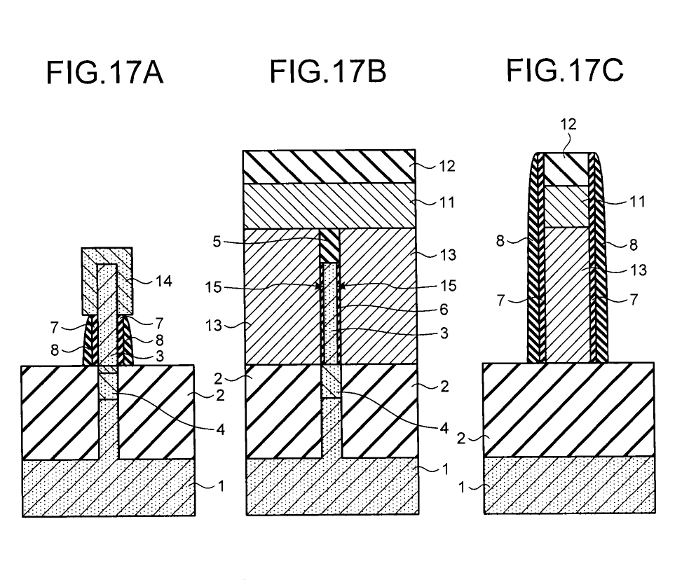

Next, as shown in FIG. 17A to FIG. 17C, a semiconductor layer 14 is formed on the surface of the upper portion of both ends of the fin-type semiconductor 3 by selective epitaxial growth. The material of the semiconductor layer 14 can be selected, for example, from Si, Ge, SiGe, GaAs, AlGaAs, InP, GaP, InGaAs, GaN, SiC, and the like.

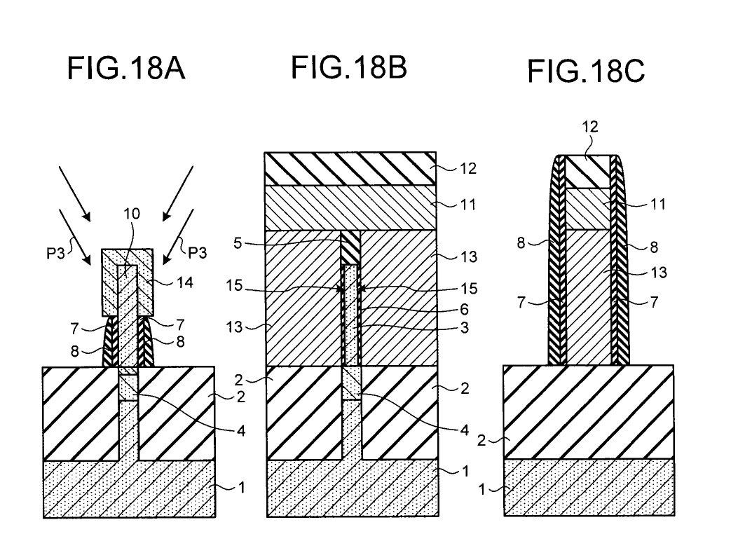

Next, as shown in FIG. 18A to FIG. 18C, an N-type impurity, such as As and P, is obliquely injected into the upper portion of both ends of the fin-type semiconductor 3 by ion implantation P3 to dope the high concentration impurity into the semiconductor layer 14 formed by selective epitaxial growth. The high-concentration impurity diffusion layer 10 and the semiconductor layer 14, which is formed on the high-concentration impurity diffusion layer 10 and is doped with the high concentration impurity, become the source/drain.

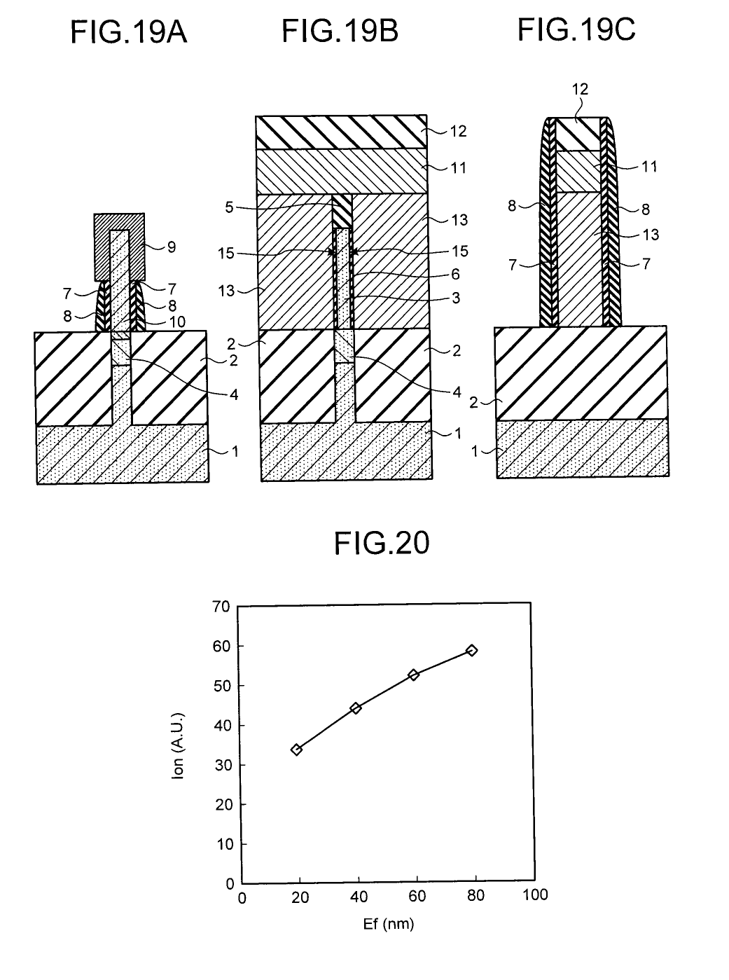

Next, as shown in FIG. 19A to FIG. 19C, part or the whole of the semiconductor layer 14 is silicided to form the silicide layer 9 on the surface of the source/drain formed of the high-concentration impurity diffusion layer 10 and the semiconductor layer 14, which is formed on the high-concentration impurity diffusion layer 10 and is doped with the high concentration impurity.

Because silicide is formed on the source/drain formed by forming the semiconductor layer 14 on the high-concentration impurity diffusion layer 10 by selective epitaxial growth, even when the width of the fin-type semiconductor 3 is small, it is possible to prevent the fin-type semiconductor 3 in the source/drain regions from being fully silicided. Consequently, the contact area between the silicide layer 9 and the fin-type semiconductor 3 can be kept large, enabling reduction of the contact resistance between the source/drain and the silicide layer 9.

The above-described embodiment explains the method of forming the silicide layer 9 on the upper portion of both ends of the fin-type semiconductor 3 after forming the semiconductor layer 14 on the upper portion of both ends of the fin-type semiconductor 3 by selective epitaxial growth, however, when the fin-type semiconductor 3 on the upper portion of the offset spacers and the sidewall spacers 8 is not fully silicided, the silicide layer 9 may be formed on the upper portion of both ends of the fin-type semiconductor 3 without forming the semiconductor layer 14 on the upper portion of both sides of the fin-type semiconductor 3.

FIG. 20 is a diagram illustrating a relationship between a fin projection amount Ef above the offset spacer 7 and the sidewall spacer 8 in FIG. 1C and on-current Ion.

In FIG. 20, when the fin projection amount Ef above the offset spacer 7 and the sidewall spacer 8 increases, the contact area between the silicide layer 9 and the fin-type semiconductor 3 becomes large and the contact resistance between the silicide layer 9 and the fin-type semiconductor 3 decreases, therefore the on-current Ion increases.

On the other hand, if the fin projection amount Hf above the buried dielectric layer 2 is constant, when the fin projection amount Ef above the offset spacer 7 and the sidewall spacer 8 increases due to retraction of the offset spacer 7 and the sidewall spacer 8, the distance between the silicide layer 9 and the junction region between the source/drain region and the punch-through stopper layer 4 decreases, which increases the junction leakage current and therefore increases the off-current Ioff.

If the fin projection amount Hf above the buried dielectric layer 2 is increased while keeping the distance between the silicide layer 9 and the PN junction region 16, the contact resistance between the source/drain and the silicide layer 9 decreases due to increase of the fin projection amount Ef without increasing the junction leakage current in the junction region 16, therefore the on-current Ion can be increased.

In the above-described embodiment, a case of forming the fin-type semiconductor 3 on a bulk substrate is explained as an example, however, it is possible to apply to the configuration in which the fin-type semiconductor 3 is formed on an SOI substrate. Moreover, in the above-described embodiment, a method of providing the offset spacer 7 on the sidewall of both end portions of the fin-type semiconductor 3 is explained, however, the offset spacer 7 may be omitted. Moreover, an N-channel type transistor is explained as the fin transistor, however, the transistor can be changed to a P-channel type transistor by changing the type of the impurity in the punch through stopper and the source/drain.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a fin-type semiconductor;
a gate electrode that is formed on a side surface of the fin-type semiconductor with a gate dielectric film therebetween in a state where both end portions of the fin-type semiconductor are exposed;
source/drain formed in both end portions of the fin-type semiconductor;
a sidewall spacer that is formed on a side surface of the source/drain in a state where a surface of an upper portion of the fin-type semiconductor in the source/drain is exposed; and
a silicide layer that is formed on a surface of the source/drain in the upper portion of the fin-type semiconductor.

2. The semiconductor device according to claim 1, wherein the sidewall spacer is formed on a side surface of the source/drain and a side surface of the gate electrode.

3. The semiconductor device according to claim 1, further comprising an offset spacer formed under the sidewall spacer.

4. The semiconductor device according to claim 1, further comprising:
a buried dielectric layer in which a lower portion of the fin-type semiconductor is buried; and
a punch-through stopper layer formed in a lower portion of the fin-type semiconductor.

5. The semiconductor device according to claim 4, wherein a distance between a junction region and the silicide layer is 30 nm or more, the junction region being formed by the source/drain and the punch-through stopper layer.

6. The semiconductor device according to claim 1, further comprising a semiconductor layer formed on an upper portion of the fin-type semiconductor in the source/drain.

7. The semiconductor device according to claim 6, wherein the silicide layer is formed in the semiconductor layer.

8. The semiconductor device according to claim 7, wherein the source/drain in an upper portion of the fin-type semiconductor is not eroded by the silicide layer.

9. The semiconductor device according to claim 1, wherein a channel region in the fin-type semiconductor is fully depleted.

10. The semiconductor device according to claim 9, wherein a fin width of the fin-type semiconductor is smaller than a gate length.

11. A manufacturing method of a semiconductor device comprising:
forming a fin-type semiconductor on a semiconductor substrate;
forming a gate dielectric film on a surface of the fin-type semiconductor;
forming a gate electrode on a side surface of the fin-type semiconductor with the gate dielectric film therebetween in a state where both end portions of the fin-type semiconductor are exposed;
forming a top layer on the gate electrode;
forming source/drain in both end portions of the fin-type semiconductor;
forming a sidewall spacer on a side surface of both end portions of the fin-type semiconductor and a side surface of the gate electrode;
exposing a surface of an upper portion of both end portions of the fin-type semiconductor by removing an upper portion of the sidewall spacer formed on both end portions of the fin-type semiconductor;
performing selective epitaxial growth of a semiconductor layer on a surface of an upper portion of both end portions of the fin-type semiconductor; and
forming a silicide layer on a surface of an upper portion of both end portions of the fin-type semiconductor by siliciding the semiconductor layer.

12. The manufacturing method of a semiconductor device according to claim 11, further comprising forming an offset spacer on a side surface of both end portions of the fin-type semiconductor and a side surface of the gate electrode before forming the sidewall spacer, wherein
an upper portion of the offset spacer formed on both end portions of the fin-type semiconductor is removed when removing an upper portion of the sidewall spacer formed on both end portions of the fin-type semiconductor.

13. The manufacturing method of a semiconductor device according to claim 12, further comprising forming a hard mask on the gate electrode and the top layer, wherein
the hard mask is thinned in a state where the hard mask remains on the top layer and the offset spacer and the sidewall spacer keep completely covering a side surface of the gate electrode and a side surface of the top layer when removing an upper portion of the offset spacer and the sidewall spacer on both end portions of the fin-type semiconductor.

14. The manufacturing method of a semiconductor device according to claim 11, wherein
the forming the fin-type semiconductor on the semiconductor substrate includes
forming a cap layer on the semiconductor substrate, and
etching the semiconductor substrate with the cap layer as a mask.

15. The manufacturing method of a semiconductor device according to claim 11, further comprising forming a buried dielectric layer on the semiconductor substrate so that an upper portion of the fin-type semiconductor is exposed and a lower portion of the fin-type semiconductor is buried.

16. The manufacturing method of a semiconductor device according to claim 15, further comprising forming a punch-through stopper layer in a lower portion of the fin-type semiconductor on a basis of large-angle scattering when an impurity is injected into the buried dielectric layer vertically.

17. The manufacturing method of a semiconductor device according to claim 16, wherein a distance between a junction region and the silicide layer is 30 nm or more, the junction region being formed by the source/drain and the punch-through stopper layer.

18. The manufacturing method of a semiconductor device according to claim 11, wherein the source/drain in an upper portion of the fin-type semiconductor is not eroded by the silicide layer.

19. The manufacturing method of a semiconductor device according to claim 11, wherein a channel region in the fin-type semiconductor is fully depleted.

20. The manufacturing method of a semiconductor device according to claim 19, wherein a fin width of the fin-type semiconductor is smaller than a gate length.
